(19) United States
(12) Patent Application Publication
(10) Pub. No.: US 2007/0098032 A1
(43) Pub. Date: May 3, 2007

(54) POLARIZATION CONTROL IN VERTICAL CAVITY SURFACE EMITTING LASERS USING OFF-AXIS EPITAXY

(75) Inventor: Ralph H. Johnson, Murphy, TX (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation, Sunnyvale, CA (US)

(21) Appl. No.: 11/549,516

(22) Filed: Oct. 13, 2006

Related U.S. Application Data
(60) Provisional application No. 60/730,798, filed on Oct. 27, 2005.

(51) Int. Cl. H01S 5/00; H01L 21/00

(52) U.S. Cl. 372/50.11; 438/46; 438/29; 438/32

(57) ABSTRACT

A polarization pinned long wavelength vertical cavity surface emitting laser (VCSEL). The VCSEL includes a III V semiconductor substrate. A bottom DBR mirror is formed on the semiconductor substrate. An active region is formed in an off-axis orientation on the bottom DBR mirror. The active region includes a surfactant that suppresses unwanted three dimensional growth. A top DBR mirror formed on the active region.

### CROSS-REFERENCE TO RELATED APPLICATIONS

This application claims the benefit of U.S. Provisional Application No. 60/730,798, titled Polarization Control In Vertical Cavity Surface Emitting Lasers Using Off-Axis Epitaxy filed Oct. 27, 2005, which is incorporated herein by reference in its entirety.

### BACKGROUND OF THE INVENTION

1. The Field of the Invention

The invention generally relates to lasers. More specifically, the invention relates to Vertical Cavity Surface Emitting Lasers (VCSELs).

2. Description of the Related Art

Lasers are commonly used in many modern components. One use that has recently become more common is the use of lasers in data networks. Lasers are used in many fiber optic communication systems to transmit digital data on a network. In one exemplary configuration, a laser may be modulated by digital data to produce an optical signal, including periods of light and dark output that represents a binary data stream. In actual practice, the lasers output a high optical output representing binary highs and a lower power optical output representing binary lows. To obtain quick reaction time, the laser is constantly on, but varies from a high optical output to a lower optical output.

Optical networks have various advantages over other types of networks such as copper wire based networks. For example, many existing copper wire networks operate at near maximum possible data transmission rates and at near maximum possible distances for copper wire technology. On the other hand, many existing optical networks exceed, both in data transmission rate and distance, the maximums that are possible for copper wire networks. That is, optical networks are able to reliably transmit data at higher rates over further distances than is possible with copper wire networks.

One type of laser that is used in optical data transmission is a Vertical Cavity Surface Emitting Laser (VCSEL). A VCSEL is typically constructed on a semiconductor wafer such as Gallium Arsenide (GaAs). The VCSEL includes a bottom mirror constructed on the semiconductor wafer. Typically, the bottom mirror includes a number of alternating high and low index of refraction layers. As light passes from a layer of one index of refraction to another, a portion of the light is reflected. By using a sufficient number of alternating layers, a high percentage of light can be reflected by the mirror.

An active region that includes a number of quantum wells is formed on the bottom mirror. The active region forms a PN junction sandwiched between the bottom mirror and a top mirror, which are of opposite conductivity type (i.e. a p-type mirror and an n-type mirror). Free carriers in the form of holes and electrons are injected into the quantum wells when the PN junction is forward biased by an electrical current. At a sufficiently high bias current the injected minority carriers, electrons and holes, form a population inversion (i.e. at an energy separation between states the product of the probability of occupation of states in the conduction band and the valence band is greater than ¼) in the quantum wells that produces optical gain. Optical gain occurs when photons in the active region cause electrons to move from the conduction band to the valance band which produces additional photons. When the optical gain is equal to the loss in the two mirrors, laser oscillation occurs. The free carrier electrons in the conduction band quantum well are stimulated by photons to recombine with free carrier holes in the valence band quantum well. This process results in the stimulated emission of photons, and produces coherent light.

The active region may also include an oxide aperture formed using one or more oxide layers formed in the top and/or bottom mirrors near the active layer. The oxide aperture serves both to form an optical cavity and to direct the bias current through the central region of the cavity that is formed.

A top mirror is formed on the active region. The top mirror is similar to the bottom mirror in that it generally comprises a number of layers that alternate between a high index of refraction and a lower index of refraction. Generally, the top mirror has fewer mirror periods of alternating high index and low index of refraction layers, to enhance light emission from the top of the VCSEL.

Illustratively, the laser functions when a current is passed through the PN junction to inject free carriers into the active region. Recombination of the injected free carriers from the conduction band quantum wells to the valence band quantum wells results in photons that begin to travel in the laser cavity defined by the mirrors. The mirrors reflect the photons back and forth. When the bias current is sufficient to produce a population inversion between the quantum well states at the wavelength supported by the cavity, optical gain is produced in the quantum wells. When the optical gain is equal to the cavity loss laser oscillation occurs and the laser is said to be at threshold bias and the VCSEL begins to ‘lase’ as the optically coherent photons are emitted from the top of the VCSEL.

The VCSEL is generally formed as a semiconductor diode. A diode is formed from a pn junction that includes a p-type material and an n-type material. In this example, p-type materials are semiconductor materials, such as Gallium Arsenide (GaAs) doped with a material such as carbon that causes free holes, or positive charge carriers to be formed in the semiconductor material. N-type materials are semiconductor materials such as GaAs doped with a material such as silicon to cause free electrons, or negative charge carriers, to be formed in the semiconductor material. Generally, the top mirror is doped with p-type dopants where the bottom mirror is doped with n-type dopants to allow for current flow to inject minority carrier electrons and holes into the active region.

One issue that arises with longer wavelength VCSELs, such as 1310 nm VCSELs, relates to polarization controls. Using polarization control helps to control feedback effects caused by portions of emitted laser light being reflected back into the laser. These reflections cause chaotic reverberations and cause noise in the laser output.

While the current designs have been acceptable for shorter wavelength VCSELs such as VCSELs emitting 850 nanometer (nm) wavelength light, longer wavelength VCSELs have been more difficult to achieve. For example a 1310 nm VCSEL would be useful in telecommunication applications. The market entry point of lasers used in 10 Gigabit Ethernet applications is 1310 nm. However, due to the optical characteristics of currently designed VCSELs as described above, 1310 nm VCSELs have not currently been feasible.

### BRIEF SUMMARY OF THE INVENTION

One embodiment includes a method of making a vertical cavity surface emitting laser (VCSEL). The method includes forming a bottom DBR mirror on a III V semiconductor substrate. The method also includes forming an active region on the bottom DBR mirror. Forming an active region includes forming the active region in an off-axis orientation using a surfactant and migration enhanced epitaxy to inhibit unwanted three dimensional growth. A top DBR mirror is formed on the active region.

Another embodiment includes a VCSEL. The VCSEL includes a III-V semiconductor substrate. A bottom DBR mirror is formed on the off axis semiconductor substrate. An active region is formed in an off-axis orientation on the off-axis bottom DBR mirror. The active region includes a surfactant that suppresses unwanted three dimensional growth. A top DBR mirror formed on the active region.

Yet another embodiment includes an optical assembly. The optical assembly includes a VCSEL. The VCSEL is fabricated in an off-axis orientation to pin polarization of the VCSEL. The VCSEL includes an active region. The active region includes a surfactant to inhibit unwanted three dimensional growth cause by seeds in the active region that exist when the active region is formed in the off-axis orientation. The assembly further includes a λ/4 waveplate optically coupled to the VCSEL. The λ/4 waveplate is configured to cause light reflected back into the VCSEL to be orthogonal to the pinned polarization of the VCSEL.

Advantageously, embodiments outlined above allow for a long wavelength VCSEL to be used in polarization sensitive applications. Namely, using polarization sensitive circulators and splitters, inexpensive signal handling can be accomplished. Further, an assembly that includes a polarization pinned VCSEL and a λ/4 wave plate can be less sensitive to reflected light.

These and other advantages and features of the present invention will become more fully apparent from the following description and appended claims, or may be learned by the practice of the invention as set forth hereinafter.

### BRIEF DESCRIPTION OF THE SEVERAL VIEWS OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates a VCSEL structure.

### DETAILED DESCRIPTION OF THE INVENTION

One embodiment improves performance of VCSELs at longer wavelengths by controlling the polarization of laser emissions from the VCSEL. This may be accomplished by fabricating the VCSEL in an off-axis orientation. To form the quantum wells in an off-axis orientation, a surfactant such as Antimony (Sb) is used. In this example the fabrication is off of the 100 orientation. Using Sb and migration enhanced epitaxy, small seeds for three dimensional growth that would normally be present are suppressed such that they are small enough and infrequent enough sufficient to allow off orientation structures without three dimensional growth. Migration enhanced epitaxy is described in more detail in U.S. patent application Ser. No. 10/931,194 filed on Aug. 31, 2004 and in related applications including application Ser. No. 09/217,223 filed Dec. 12, 1998; Ser. No. 10/026,016 filed Dec. 20, 2001, Ser. No. 10/026,019 filed Dec. 20, 2001, Ser. No. 10/026,044 filed Dec. 27, 2001 and Ser. No. 10/026,020 filed Dec. 27, 2001. Each of the cited applications is incorporated herein in their entireties.

By forming the quantum wells in an off-axis crystal orientation, the polarization can be pinned. This allows optical isolation to be accomplished by using an inexpensive quarter wave plate. Polarized light from the VCSEL passing through the quarter wave plate and being reflected back through the quarter wave plate is orthogonal to the light emitted from the VCSEL. As such, the VCSEL will be insensitive to this reflected light. Therefore, long wavelength VCSELs can be fabricated for applications that require polarization stability.

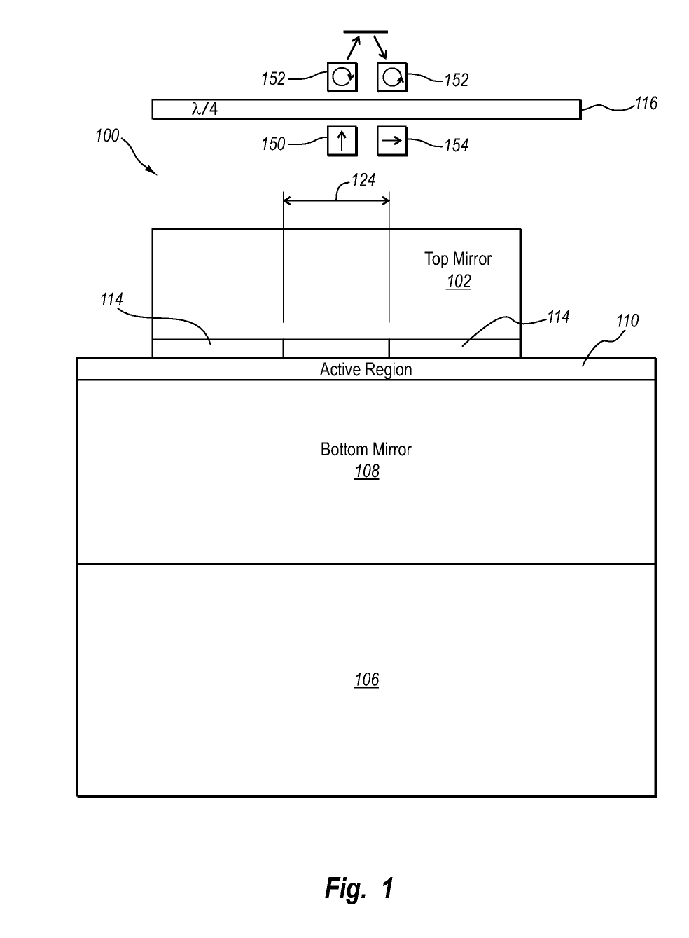

With reference now FIG. 1 an illustrative embodiment includes a VCSEL 100 with a top mirror 102. The VCSEL is formed from an epitaxial structure that includes various layers of semiconductor. The VCSEL 100 is formed on a substrate 106. The substrate 106, in this example, is a gallium arsenide (GaAs) substrate. In other embodiments, the substrate 106 may be other material such as other III V semiconductor materials. The VCSEL 100 may be formed in an off-axis orientation using, for example, by using Molecular Beam Epitaxy (MBE).

A bottom mirror 108 is formed on the substrate 106. The bottom mirror 108 is a distributed Bragg reflector (DBR) mirror that includes a number of alternating layers of high and low index of refraction materials. In the example shown, the bottom mirror 108 includes alternating layers of aluminum arsenide (AlAs) and gallium arsenide (GaAs).

An active region 110 is formed on the bottom mirror 108. The active region 110 includes quantum wells. The central region of the quantum wells under an oxide aperture 124 may also be referred to as the optical gain region. This central region of the quantum wells is the location where current through the active region 110 and the presence of injected free carriers causes population inversion and optical gain. These free carriers transitioning from conduction band quantum well states to valence band quantum well states (i.e. across the band gap) cause the emission of photons. An oxide layer 114 is formed above the active layer 110 to provide an aperture 124 for lateral definition of the laser optical cavity and for directing bias current to the central region of the VCSEL active region 110.

As discussed previously, when growing the portion of the epitaxial structure that includes the quantum wells of the active layer 110, a surfactant such as Antimony (Sb) may be used to inhibit three-dimensional growth caused by small seeds formed when the epitaxial structure is formed off-axis.

The Sb may be used in one embodiment in the active region 110. In other embodiments, the Sb is used in layers adjacent to the active region and in the active region. The active region may include, for example, 1% Sb and 2% Nitrogen. One method of fabricating an epitaxial structure includes processing at a beam equivalent Sb pressure of about 8×10⁻⁸ torr.

To accomplish effective polarization pinning, the quantum wells are oriented towards a 111A or 111B direction. The orientation does not need to be precisely in a 111 direction, but testing has shown that off-axis orientations in this direction are preferable. Notably, formation in a 110 direction does not seem to provide much benefit as no asymmetry is caused by such an off-axis orientation.

Further, the quantum wells should be formed sufficiently off-axis. In one embodiment, the quantum wells are at least 6° off-axis in a 111 direction. In another embodiment, the quantum wells are formed at a 311 orientation, which is 29.5° off the 100 orientation.

In alternative embodiments, there are other growth related asymmetries which may be used to pin the polarization allowing for far less misorientation, and allowing the polarization pinning to work with other off-axis orientation cuts. For example, molecular steps which occur in material with any degree of off-axis orientation may be used to pin polarization. Once again using a surfactant like Sb is beneficial for the same reasons it was for the higher degrees of misorientation. Generally the height of the steps which occur can vary as multiple single molecular layer steps are combined into one step to make taller steps. Taller steps can be enhanced according to growth conditions by choosing higher temperatures or lower V/III ratios for the lower mirror and a spacer located a lower point than would ordinarily be used which enhance the surface mobility. The orientation of these steps is controlled by the direction of off-axis orientation of the substrate and the subsequent epitaxial growth.

Other asymmetries in the VCSEL layout are used in conjunction with the off-axis orientation. Stated differently, layout asymmetries should be used in a manner which works with the intentional substrate mis-orientation. Such asymmetries include, for example, thermal asymmetries resulting from how metal is deposited on the epitaxial structure, mechanical asymmetries caused by various etching processes such as the formation of trenches, electrical asymmetries caused by a particular method of current injection, and the like. These asymmetries also contribute to polarization pinning and thus can either complement or oppose polarization effects caused by off-axis growth of the epitaxial structure. These other asymmetries are discussed for example in the following articles:

“Single-Mode, Single-Polarization VCSELs via Elliptical Surface Etching: Experiments and Theory”, Pierluigi Debernardi, et al., IEEE Journal of Selected Topics in Quantum Electronics, Vol. 9, No. 5, September/October 2003

“Polarization-Controlled 850-nm-Wavelength Vertical-Cavity Surface-Emitting Lasers Grown on (311)B Substrates by Metal-Organic Chemical Vapor Deposition”, Hiroyuki Uenohara, et al., IEEE Journal of Selected Topics in Quantum Electronics, Vol. 5, No. 3, May/June 1999

“Asymmetric Current Injection for Polarization Stabilization in Vertical-Cavity Surface-Emitting Lasers”, G. Verschaffelt, et al., COBRA Inter-University Research Institute on Communication Technology, Eindhoven University of Technology, Department of Electrical Engineering, Eindhoven, Belgium

“Stable Linearly Polarized Light Emission from VCSELs with Oxidized Elliptical Current Aperture”, U. Fiedler, et al., University of Ulm, Dept. of Optoelectronics, Ulm, Germany

“Design and Modeling of Polarization-Stable Surface-Etched VCSELs”, H. J. Unold, et. al., University of Ulm, Optoelectronics Dept., Ulm, Germany

“Optical feedback control of polarization switching in vertical-cavity surface-emitting lasers”, Yanhua Hong(1), et al., University of Wales, Bangor, School of Informatics, Bangor, Wales, UK; Instituto de Fisica, Facultad de Ciencias, Universidad de la Republica, Montevideo, Uruguay

“Dynamically Stable Polarization Characteristics of Oxide-Confinement Vertical-Cavity Surface-Emitting Lasers Grown on GaAs (311)A Substrate”, M. Takahashi, et. al., ATR Adaptive Communications Research Laboratories, Kyoto, Japan; A. Mizutani, et. al., Tokyo Institute of Technology, Precision and Intelligence Laboratory, Yokohama, Japan

“Polarization Anisotropy in Asymmetric Oxide—aperture VCSELs”, Kyoung-Ho HA, et al, Department of Physics, Korea Advanced Institute of Science and Technology, Taejon, Korea

Determining the best layout asymmetries can be difficult to determine in advance so devices with symmetries along the flat/cleavage plane and perpendicular need to be assessed to determine which way the polarization tends to be pinned.

Referring once again to FIG. 1, an assembly may be constructed that includes a VCSEL 100 optically coupled to a λ/4 wave plate 116. Optically coupling means that the VCSEL 100 is oriented with the λ/4 wave plate 116 such that laser light from the VCSEL 100 is directed towards the λ/4 wave plate 116. Polarization pinning causes light emitted from the VCSEL 100 to be in a first orientation 150. When the polarized light passes through the λ/4 wave plate 116 the phase delay shifts so that the light becomes circularly polarized as illustrated at 152. When the reflected light passes through the λ/4 wave plate 116 a second time, the light is converted from circularly polarized light to linearly polarized light in a direction, as shown at 154, orthogonal to the initial polarization shown at 150. As such, the VCSEL 100 is insensitive to reflected light in a polarization which is orthogonal to the direction emitted from the laser.

Notably, the embodiments described above are particularly useful in long wavelength, 1300 nm and above, VCSEL applications. In particular, by having a polarization pinned VCSEL, long wavelength VCSELs can be used in applications that are sensitive to polarization. For example various inexpensive types of components such circulators, splitters, multiplexors, and the like may be used in multiplexing and signal handling when those components function based on a polarization of an incoming light. In addition, by using an assembly with a polarization pinned VCSEL and a λ/4 wave plate as described above, the assembly can be less sensitive to reflected light.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A method of fabricating a long wavelength VCSEL, the method comprising:
forming an off-axis orientation bottom DBR mirror on an off-axis orientation III V semiconductor substrate;
forming an active region on the off-axis orientation bottom DBR mirror, wherein forming an active region comprises forming the active region in an off-axis orientation using a surfactant to inhibit unwanted three dimensional growth; and
forming a top DBR mirror on the active region.

2. The method of claim 1, wherein the III V semiconductor substrate is GaAs.

3. The method of claim 1, wherein the surfactant is Antimony.

4. The method of claim 1, wherein forming an active region includes using about 1% Antimony and 2% Nitrogen.

5. The method of claim 1, wherein the acts recited are performed at a pressure of about 8×10⁻⁸ torr SB beam equivalent pressure.

6. The method of claim 1, wherein forming an active region in an off-axis orientation comprises forming the active region in a 111A or 111B direction.

7. The method of claim 1, wherein forming an active region in an off-axis orientation comprises forming the active region in a 311 orientation.

8. The method of claim 1, wherein forming an active region in an off-axis orientation comprises forming the active region in a minimal off-axis orientation.

9. The method of claim 1, further comprising forming a layout asymmetry that includes a thermal asymmetry formed by a metal deposition pattern.

10. The method of claim 1, further comprising forming a layout asymmetry that includes a mechanical asymmetry formed by a trench pattern.

11. The method of claim 1, further comprising forming a layout asymmetry that includes an electrical asymmetry caused by a current injection method.

12. The method of claim 1, further comprising forming an an assembly by optically coupling a ¼ waveplate to the VCSEL.

13. The method of claim 1, wherein forming an active region comprises forming the active region in an off-axis orientation using migration enhanced epitaxy.

14. The method of claim 1, wherein forming an active region comprises using appropriate growth conditions to create sufficient step heights and densities to pin polarization.

15. A long wavelength VCSEL comprising:
an off-axis orientation III V semiconductor substrate;
a bottom off-axis orientation DBR mirror formed on the off-axis orientation semiconductor substrate;
an active region formed in an off-axis orientation on the bottom DBR mirror, the active region comprising a surfactant that suppresses unwanted three dimensional growth; and
a top DBR mirror formed on the active region.

16. The VCSEL of claim 15 wherein the III V semiconductor substrate is GaAs.

17. The VCSEL of claim 15, wherein the surfactant is Antimony.

18. The VCSEL of claim 15, the active region includes about 1% Antimony and 2% Nitrogen.

19. The VCSEL of claim 15, wherein the active region is in an off-axis orientation in a 111A or 111B direction.

20. The VCSEL of claim 15, wherein the active region in an off-axis orientation in a 311 orientation.

21. The VCSEL of claim 15, further comprising a thermal asymmetry formed by a metal deposition pattern.

22. The VCSEL of claim 15, further comprising a mechanical asymmetry formed by a trench pattern.

23. The VCSEL of claim 15, further comprising an electrical asymmetry caused by a current injection method.

24. An optical assembly comprising:
a long wavelength VCSEL, wherein the VCSEL is fabricated in an off-axis orientation to pin polarization of the VCSEL, wherein the VCSEL comprises an active region, the active region comprising a surfactant to inhibit unwanted three dimensional growth cause by seeds in the active region that exist when the active region is formed in the off-axis orientation; and
a λ/4 waveplate optically coupled to the VCSEL and configured to cause light reflected back into the VCSEL to be orthogonal to the pinned polarization of the VCSEL.
